(19) United States
(12) Patent Application Publication
(10) Pub. No.: US 2014/0091317 A1
(43) Pub. Date: Apr. 3, 2014

(54) METHOD OF MANUFACTURING SEMICONDUCTOR CRYSTAL SUBSTRATE, METHOD OF MANUFACTURING SEMICONDUCTOR APPARATUS, SEMICONDUCTOR CRYSTAL SUBSTRATE, AND SEMICONDUCTOR APPARATUS

(71) Applicant: FUJITSU LIMITED, Kawasaki-shi (JP)

(72) Inventors: Shuichi TOMABECHI, Atsugi (JP); JUNJI KOTANI, Isehara (JP); NORIKAZU NAKAMURA, Sagamihara (JP)

(21) Appl. No.: 13/943,891

(22) Filed: Jul. 17, 2013

(30) Foreign Application Priority Data
Sep. 28, 2012 (JP) 2012-218248

(51) Int. Cl. H01L 21/02; H01L 29/20; H01L 29/778; H01L 29/66

(52) U.S. Cl. CPC H01L 21/0254; H01L 29/66431; H01L 29/2003; H01L 29/778
USPC 257/76; 438/479; 438/172

(57) ABSTRACT

A method of manufacturing a semiconductor crystal substrate, includes forming a nitride layer by supplying a gas including a nitrogen component to a substrate formed of a material including silicon and nitriding a surface of the substrate; and forming an AlN layer on the nitride layer by supplying the gas including the nitrogen component and a source gas including Al.

### CROSS-REFERENCE TO RELATED APPLICATIONS

This application is based upon and claims the benefit of priority of the prior Japanese Patent Application No. 2012-218248, filed on Sep. 28, 2012, the entire contents of which are incorporated herein by reference.

### FIELD

The embodiment discussed herein is related to a method of manufacturing a semiconductor crystal substrate, a method of manufacturing a semiconductor apparatus, a semiconductor crystal substrate, and a semiconductor apparatus.

### BACKGROUND

A nitride semiconductor such as GaN, AlN, InN and the like and a material of a mixed crystal thereof have a wide band gap, so as to be used as a high-power electronic device or a short-wavelength light-emitting device. Among these, research and development has been conducted on the technologies of a Field-Effect Transistor (FET) and especially a High Electron Mobility Transistor (HEMT) as a high-power device (see, for example, Japanese Laid-open Patent Publication No. 2002-359256).

The HEMT using such a nitride semiconductor is used in a high-power and highly-efficient amplifier, a high-power switching device and the like.

In the HEMT using such a nitride semiconductor, an aluminum gallium nitride/gallium nitride (AlGaN/GaN) heterostructure is formed on the substrate, so that the GaN layer thereof may serve as an electron transit layer. Further, the substrate may be formed of sapphire, silicon carbide (SiC), gallium nitride (GaN), silicon (Si) or the like.

Among the nitride semiconductors, for example, GaN has excellent electronic characteristics because of its higher withstand-voltage characteristic due to its higher saturated electron speed and wider band gap.

Further, GaN has a wurtzite-type crystal structure, so as to have its polarity in [0001] direction which is parallel to the c-axis. Further, when the AlGaN/GaN heterostructure is formed, a piezoelectric polarization may be excited due to lattice distortion caused by a difference in lattice constants between AlGaN and GaN.

Therefore, highly-concentrated Two-Dimensional Electron Gas (2DEG) may be generated in a region near a boundary surface of the GaN layer. Such a nitride semiconductor layer formed of GaN, AlGaN or the like may be formed by epitaxial growth using Metal Organic Chemical Vapor Deposition (MOCVD).

However, when the nitride semiconductor layer is formed on a silicon substrate by MOCVD, a melt-back reaction between silicon and gallium may occur. Therefore, to avoid the occurrence of the melt-back reaction, an AlN template, in which an AlN layer is formed on the silicon substrate, is used.

Therefore, when, for example, a HEMT using the nitride semiconductor is manufactured, the nitride semiconductor layer is formed on the AlN layer of the AlN template which is a semiconductor crystal substrates.

### SUMMARY

According to an aspect, a method of manufacturing a semiconductor crystal substrate, the method includes forming a nitride layer by supplying a gas including a nitrogen component to a substrate formed of a material including silicon and nitriding a surface of the substrate; and forming an AlN layer on the nitride layer by supplying the gas including the nitrogen component and a source gas including Al.

The objects and advantages of the embodiments disclosed herein will be realized and attained by means of the elements and combinations particularly pointed out in the claims.

It is to be understood that both the foregoing general description and the following detailed description are exemplary and explanatory and are not restrictive of the invention as claimed.

### BRIEF DESCRIPTION OF DRAWINGS

FIG. 1 illustrates an example configuration of a semiconductor crystal substrate according to a first embodiment of the present invention;

FIGS. 2A, 2B, and 2C illustrate an example method of manufacturing the semiconductor crystal substrate according to a first embodiment;

FIG. 3 is an example configuration of a semiconductor apparatus according to a second embodiment;

FIGS. 4A and 4B are example configurations of other semiconductor apparatuses according to the second embodiment;

FIGS. 5A, 5B, and 5C illustrate an example method of manufacturing the semiconductor apparatus according to the second embodiment;

FIGS. 6A and 6B illustrate the example method of manufacturing the semiconductor apparatus according to the second embodiment;

FIG. 7 is a correlation diagram illustrating relationship between a time period for forming a nitride layer and an FWHM of a diffraction peak in an electron transit layer;

FIGS. 8A, 8B, and 8C illustrate AFM images on the surfaces of the nitride layer;

FIGS. 9A and 9B illustrate the AFM images on the surfaces of the electron transit layer;

FIG. 10 illustrates an example discretely-packaged semiconductor device according to a third embodiment;

FIG. 11 is an example circuit diagram of a power device according to the third embodiment; and

FIG. 12 illustrates an example configuration a high-power amplifier according to the third embodiment.

### DESCRIPTION OF EMBODIMENT

In a case where the AlN template is used, depending on the AlN template, the crystal quality of the GaN layer or the like formed on the AlN template may be damaged. As a result, electronic characteristics of the manufactured HEMT may be degraded. For example, the on-resistance value may be increased.

Therefore, it is desired to provide a semiconductor crystal substrate and a method of manufacturing the semiconductor crystal substrate for manufacturing a semiconductor apparatus having excellent electronic properties and including the nitride semiconductor layer having excellent crystal quality.

Further, it is also desired to provide a semiconductor apparatus and a method of manufacturing the semiconductor apparatus having excellent electronic properties and including the nitride semiconductor layer having excellent crystal quality.

In the following, embodiments of the present invention are described. Further, the same reference numerals are used to describe the same elements, and the repeated descriptions thereof may be omitted.

### First Embodiment

### Semiconductor Crystal Substrate

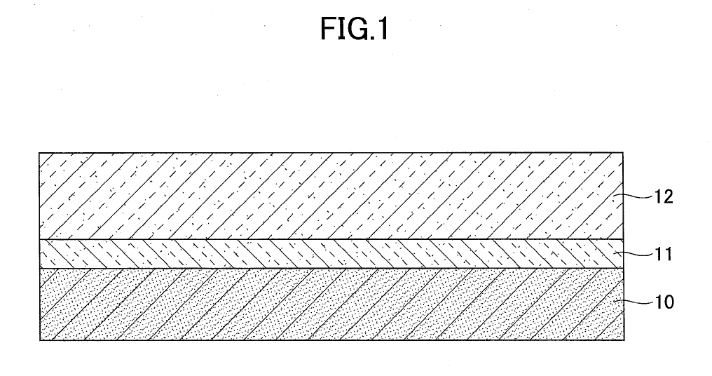

A semiconductor crystal substrate according to a first embodiment of the present invention is described. As illustrated in FIG. 1, a semiconductor crystal substrate in this embodiment is called an “AlN template”, in which a nitride layer 11 is formed on a substrate 10, which is formed of silicon (Si) or the like, and an AlN layer 12 is formed on the nitride layer 11.

The substrate 10 may be formed of a material including Si (e.g., SiC) as well as Si. Further, the nitride layer 11 is formed of a material, which includes silicon and nitrogen, such as SiN (silicon nitride), SiON or the like. The thickness of the formed nitride layer 11 is in a range from 2 nm to 5 nm (i.e. greater than or equal to 2 nm and less than or equal to 5 nm), preferably in a range from 2 nm to 3 nm. When the nitride layer 11 is too thin, it may become difficult to obtain a desired effect described below.

### Method of Manufacturing a Semiconductor Crystal Substrate

Next, a method of manufacturing a semiconductor crystal substrate according to this embodiment is described. The semiconductor crystal substrate described herein is formed using an MOCVD apparatus.

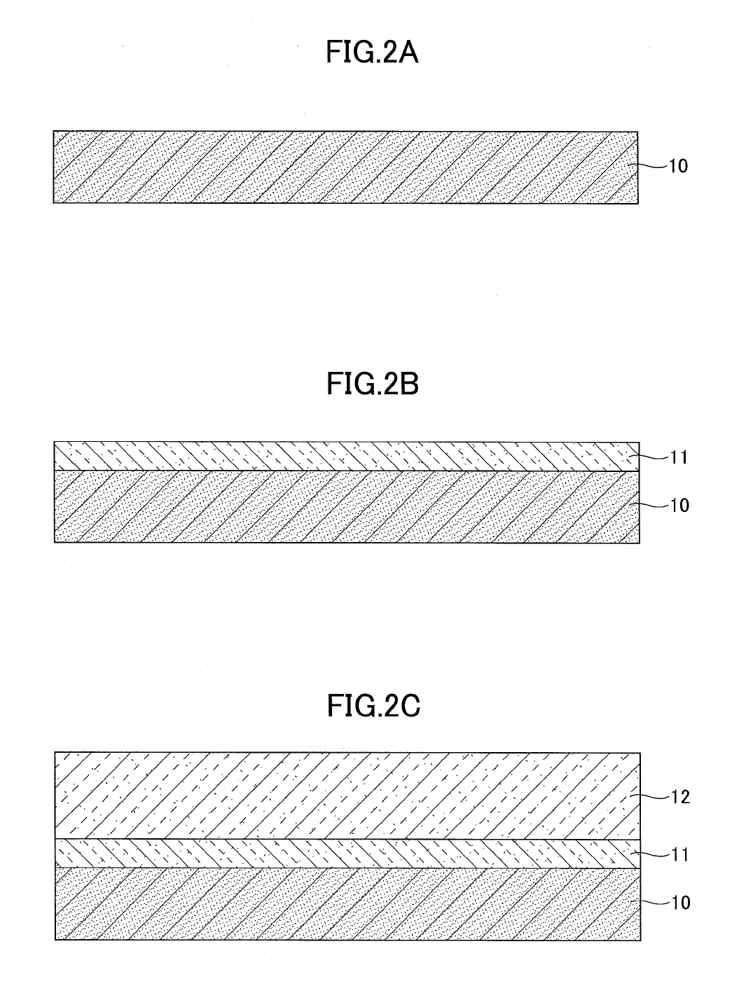

First, as illustrated in FIG. 2A, the substrate 10 formed of silicon or the like is prepared and placed into the chamber of the MOCVD apparatus. The substrate 10 formed of silicon or the like is a silicon (111) substrate.

Next, as illustrated in FIG. 2B, the nitride layer 11 formed on the surface of the substrate 10 formed of silicon or the like. Specifically, the substrate 10 is placed in the chamber of the MOCVD apparatus. Then, air is evacuated from the chamber, and hydrogen or nitrogen atmosphere is generated in the chamber. Then, the substrate 10 is heated until the temperature of the substrate 10 is 1,000° (degrees Celsius).

After that, ammonia (NH₃) is supplied into the chamber, so that the nitrogen component of ammonia introduced into the chamber reacts with silicon on the surface of the substrate 10 to form a SiN layer, which is the nitride layer 11, on the surface of the substrate 10.

To form the SiN layer (i.e., the nitride layer 11) using ammonia like this, it is preferable that the substrate temperature is in a range from 800° (degrees Celsius) and 1,100° (degrees Celsius). By doing this, the nitride layer 11 having a thickness in a range from 2 nm to 5 nm, preferably in a range from 2 nm to 3 nm, is formed on the surface of the substrate 10.

The nitride layer 11 formed as described above may be formed of, for example, SiON including remaining oxygen. Further, in the above description, a case is described where ammonia (NH₃) is supplied into the chamber. However, for example, nitrogen (N2) gas may be introduced into the chamber to generate plasma, so as to nitride the silicon on the surface of the substrate 10 to form the SiN layer (i.e., the nitride layer 11).

Next, as illustrated in FIG. 2C, the AlN layer 12 is formed. Specifically, in a state where ammonia is supplied in the chamber, trimethyl aluminum (TMA) is further supplied into the chamber.

By doing this, due to the epitaxial growth using MOCVD where ammonia and TMA are used as the source gas, the AlN layer 12 is formed on the nitride layer 11. The thickness of the AlN layer 12 formed as described above is approximately 200 nm. Further, as described above, the nitride layer 11 and the AlN layer 12 may be sequentially formed.

Specifically, after a predetermined time period has passed since ammonia is supplied, TMA may be supplied. By doing this, the nitride layer 11 and the AlN layer 12 may be laminated (sequentially formed) on the substrate 10. Further, when a substrate, in which boron (B) is injected (doped), is used as the substrate 10, boron (B) may be mixed into the nitride layer 11.

As described above, the AlN template (i.e., the semiconductor crystal substrate according to this embodiment) may be formed (manufactured).

### Second Embodiment

### Semiconductor Apparatus

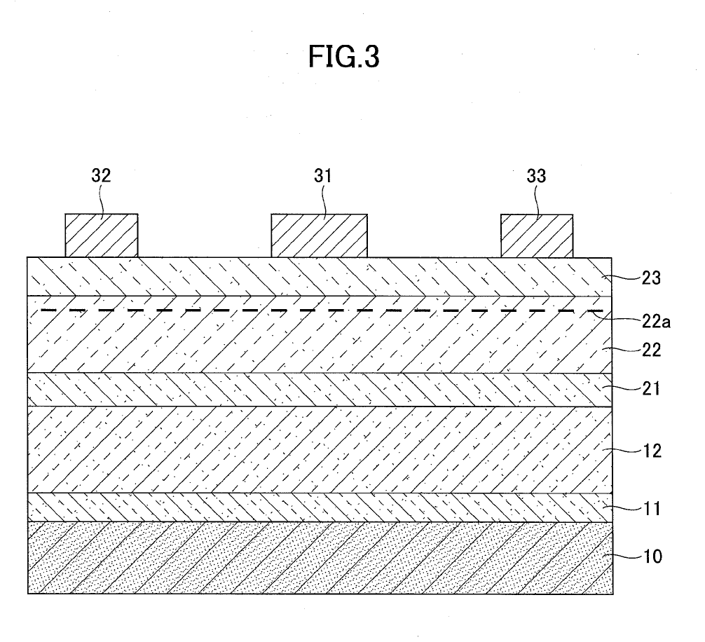

Next, a second embodiment of the present invention is described. In this embodiment, a semiconductor apparatus using the semiconductor crystal substrate according to the first embodiment is provided. With reference to FIG. 3, the semiconductor apparatus in this embodiment is described.

In the semiconductor apparatus in this embodiment, the nitride layer 11, the AlN layer 12, a buffer layer 21, an electron transit layer 22, an electron supply layer 23 and the like are laminated and formed on the substrate 10 which is formed of silicon or the like.

By doing this, in the electron transit layer 22, 2DEG 22a is formed in a region near the boundary surface between the electron transit layer 22 and the electron supply layer 23. Further, in the semiconductor apparatus in this embodiment, a gate electrode 31, a source electrode 32, and a drain electrode 33 are formed on the electron supply layer 23.

Further, in this embodiment, the semiconductor crystal substrate according to the first embodiment is used in which the nitride layer 11 and the AlN layer 12 are formed on the substrate 10.

Further, in this embodiment, the buffer layer 21 is formed of an AlGaN layer having a thickness of approximately 800 nm, the electron transit layer 22 is formed of a GaN layer having a thickness of approximately 1,200 nm, and the electron supply layer 23 is formed of an AlGaN layer having a thickness of approximately 20 nm.

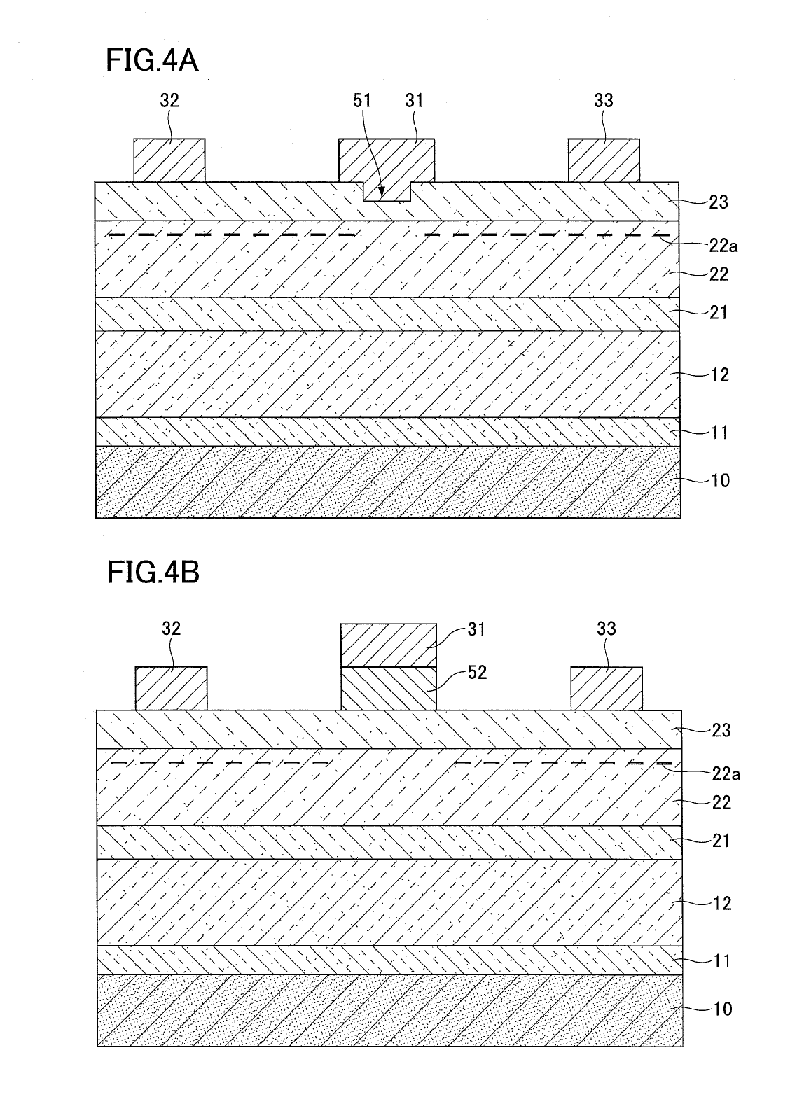

Further, in this embodiment, as illustrated in FIG. 4A, a recess 51 may be formed just under the gate electrode 31 by removing a part of the electron supply layer 23 just under the gate electrode 31, so that the gate electrode 31 is formed in the recess 51. By doing this, it may become possible to remove (eliminate) the 2DEG 22a just under the gate electrode 31 and achieve a normally-off operation.

Further, as illustrated in FIG. 4B, a p-GaN layer 52 may be formed between the electron supply layer 23 and the gate electrode 31. By doing this, similarly, it may become possible to remove (eliminate) the 2DEG 22a just under the gate electrode 31 and achieve a normally-off operation.

### Method of Manufacturing Semiconductor Apparatus

Next, a method of manufacturing the semiconductor apparatus according to this embodiment is described. The semiconductor apparatus according to this embodiment may be formed by using the semiconductor crystal substrate according to the first embodiment.

However, in this embodiment, a method of manufacturing the semiconductor including the steps of forming the semiconductor crystal substrate according to the first embodiment is described.

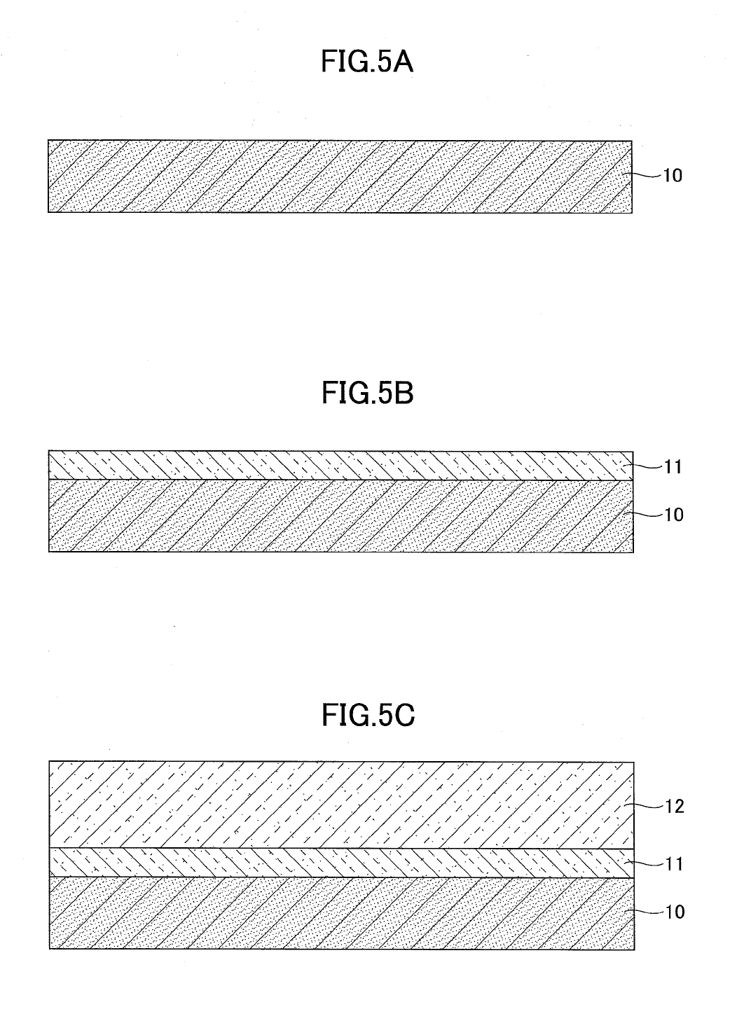

First, as illustrated in FIG. 5A, the substrate 10 formed of silicon or the like is prepared and placed into the chamber of the MOCVD apparatus. The substrate 10 formed of silicon or the like is a silicon (111) substrate.

Next, as illustrated in FIG. 5B, the nitride layer 11 formed on the surface of the substrate 10 is formed of silicon or the like. Specifically, the substrate 10 is placed in the chamber of the MOCVD apparatus.

Then, air is evacuated from the chamber, and hydrogen or nitrogen atmosphere is generated in the chamber. Then, the substrate 10 is heated until the temperature of the substrate 10 is 1,000° (degrees Celsius).

After that, ammonia (NH₃) is supplied into the chamber, so that the nitrogen component of ammonia introduced into the chamber reacts with silicon on the surface of the substrate 10 to form a SiN layer, which is the nitride layer 11, on the surface of the substrate 10.

To form the SiN layer (i.e., the nitride layer 11) using ammonia like this, it is preferable that the substrate temperature is in a range from 800° (degrees Celsius) and 1,100° (degrees Celsius).

By doing this, the nitride layer 11 having a thickness in a range from 2 nm to 5 nm, preferably in a range from 2 nm to 3 nm, is formed on the surface of the substrate 10. The nitride layer 11 formed as described above may be formed of, for example, SiON including remaining oxygen. Further, in the above description, a case is described where ammonia (NH₃) is supplied into the chamber.

However, for example, nitrogen (N2) gas may be introduced into the chamber to generate plasma, so as to nitride the silicon on the surface of the substrate 10 to form the SiN layer (i.e., the nitride layer 11).

Next, as illustrated in FIG. 5C, the AlN layer 12 is formed. Specifically, in a state where ammonia is supplied in the chamber, trimethyl aluminum (TMA) is further supplied into the chamber. By doing this, due to the epitaxial growth using MOCVD where ammonia and TMA are used as the source gas, the AlN layer 12 is formed on the nitride layer 11. The thickness of the AlN layer 12 formed as described above is approximately 200 nm.

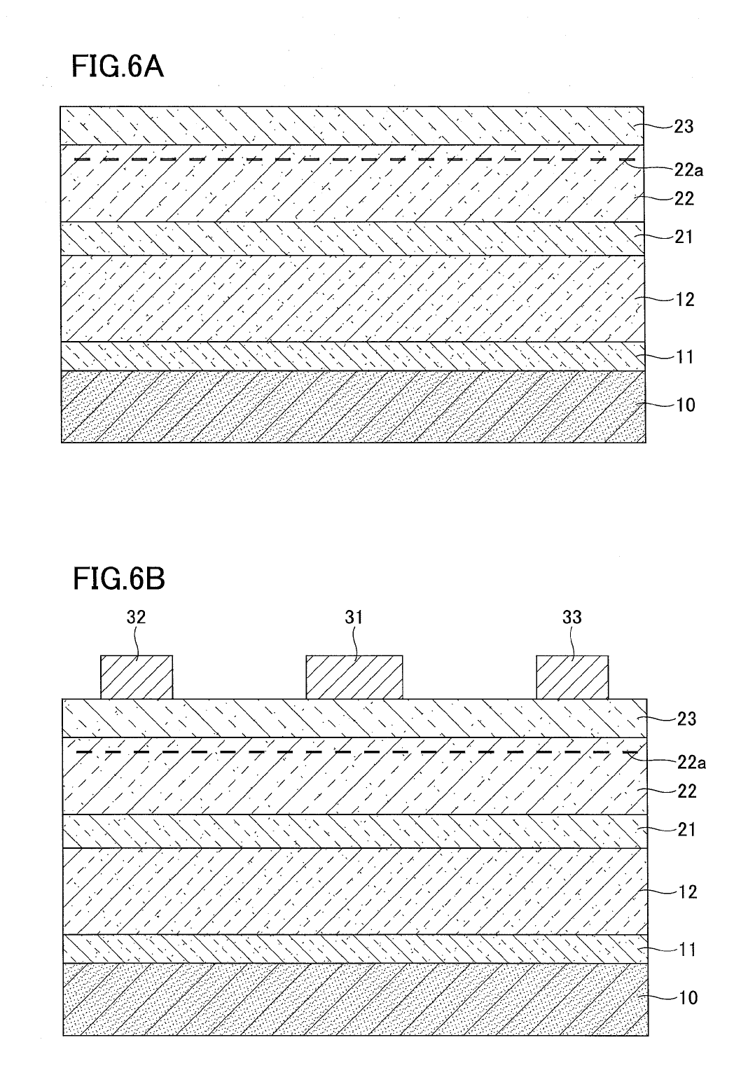

Next, as illustrated in FIG. 6A, the buffer layer 21, the electron transit layer 22, and the electron supply layer 23 are laminated (sequentially formed) on the AiN layer 12 by epitaxial growth using MOCVD.

Specifically, as the buffer layer 21, an AlGaN layer having a thickness of approximately 800 nm is formed. As the electron transit layer 22, a GaN layer having a thickness of approximately 1,200 nm is formed. As the electron supply layer 23, an AlGaN layer having thickness of approximately 20 nm is formed. By doing this, the 2DEG 22a is formed in a region near the boundary surface between the electron transit layer 22 and the electron supply layer 23.

Further, when the buffer layer 21 and the electron supply layer 23 are formed, TMA, trimethyl gallium (TMG), and NH₃ are used as the source gas. Further, when the electron transit layer 22 is formed, TMA and NH₃ are used as the source gas.

Next, as illustrated in FIG. 6B, the gate electrode 31, the source electrode 32, and the drain electrode 33 are formed on the electron supply layer 23.

By doing this, the semiconductor apparatus according to this embodiment may be (formed) manufactured.

### Nitride Layer 11

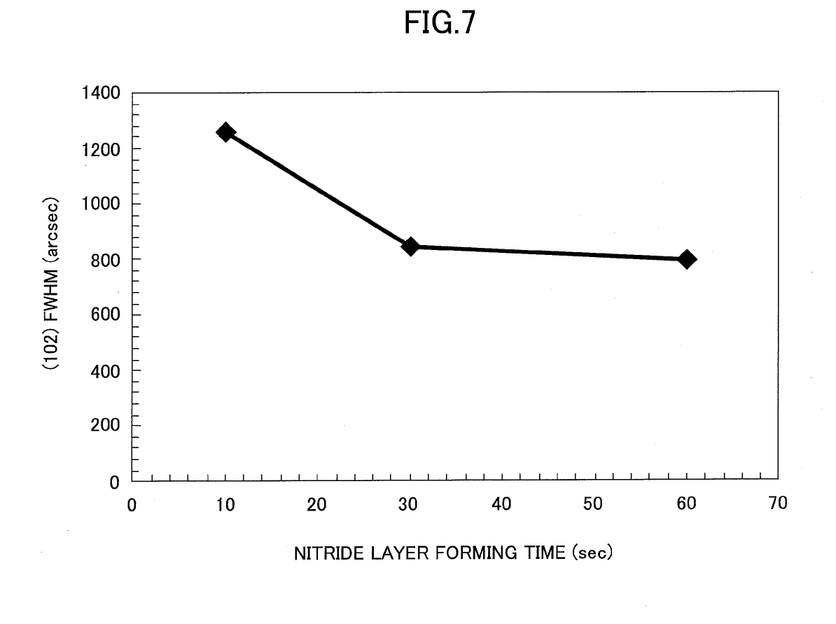

Next, a relationship between the nitride layer 11 and the crystal quality of the electron transit layer 22 and the like is described. FIG. 7 schematically illustrates a relationship between a time period for forming the nitride layer 11 and a Full Width at Half Maximum (FWHM) value of a diffraction peak of X-ray diffraction in a (102) surface of the GaN layer which becomes the electron transit layer 22 formed on the nitride layer 11.

As illustrated in FIG. 7, by increasing the time period for forming the nitride layer 11 (i.e., by increasing the time period for supplying ammonia into the chamber), the FWHM value may be reduced. Namely, the crystal quality of the electron transit layer 22 may be improved.

Specifically, when the time period for forming the nitride layer 11 is thirty seconds or more, the crystal quality in the electron transit layer 22 may be improved when compared with the case where the time period for forming the nitride layer 11 is ten seconds or less.

For example, when the time period for forming the nitride layer 11 is ten seconds, the FWHM value of the diffraction peak in the electron transit layer 22 is 1,256 arcsec. On the other hand, when the time period for forming the nitride layer 11 is sixty seconds, the FWHM value of the diffraction peak in the electron transit layer 22 is 796 arcsec. As described above, by increasing the time period for forming the nitride layer 11 to thirty seconds or more, the crystal quality in the electron transit layer 22 formed on the nitride layer 11 may be improved.

By doing this, the on-resistance value of the HEMI which is the manufactured semiconductor apparatus may be decreased. Further, the film thickness of the nitride layer 11 formed as described above is in a range from 2 nm to 5 nm, preferably in a range from 2 nm to 3 nm.

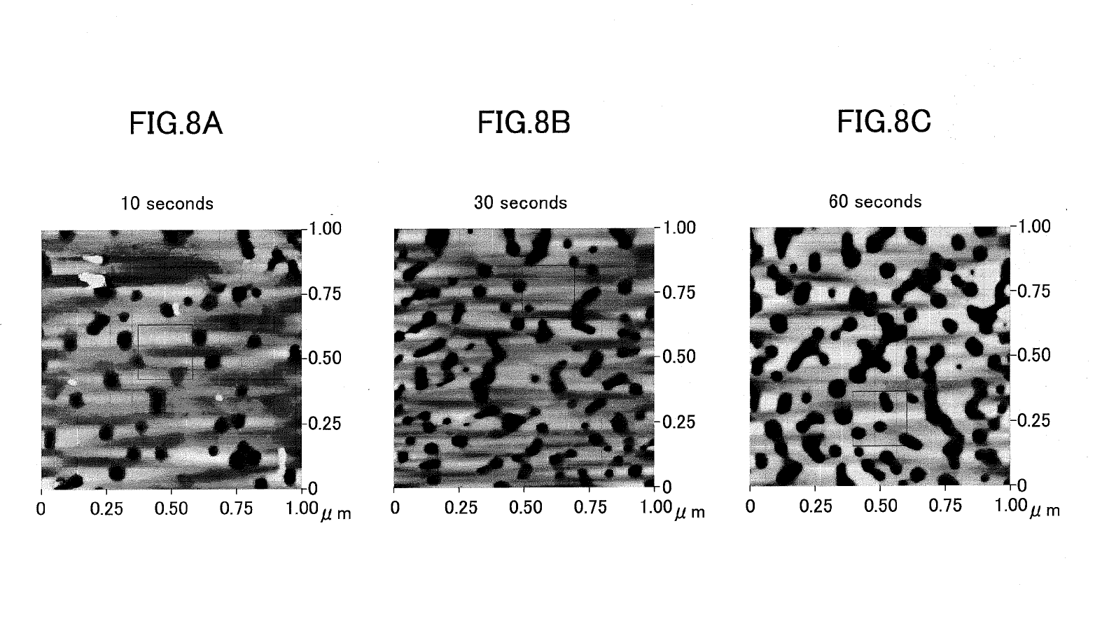

Next, the relationship between the time period for forming the nitride layer 11 (“forming time period”) and a surface state of the nitride layer 11 is described. FIGS. 8A through 8C illustrates Atomic Force Microscope (AFM) images on the surface of the nitride layer 11. Specifically, FIG. 8A illustrates the AFM image of the nitride layer 11 when the forming time period is ten seconds.

FIG. 8B illustrates the AFM image of the nitride layer 11 when the forming time period is thirty seconds. FIG. 8C illustrates the AFM image of the nitride layer 11 when the forming time period is sixty seconds. As illustrated in FIGS. 8A through 8C, as the forming time period of the nitride layer 11 is increased, the number of the black concave parts is accordingly increased.

When the number of the black concave parts is increased on the surface of the nitride layer 11, dislocation is more likely to be prevented in the buffer layer 21 formed on the nitride layer 11.

Accordingly, the number of dislocations in the electron transit layer 22 formed on the buffer layer 21 may also be decreased. As a result, it is thought that, as illustrated in FIG. 7, the FWHM value in the electron transit layer 22 may be decreased, and accordingly, the crystal quality of the electron transit layer 22 may be improved (enhanced).

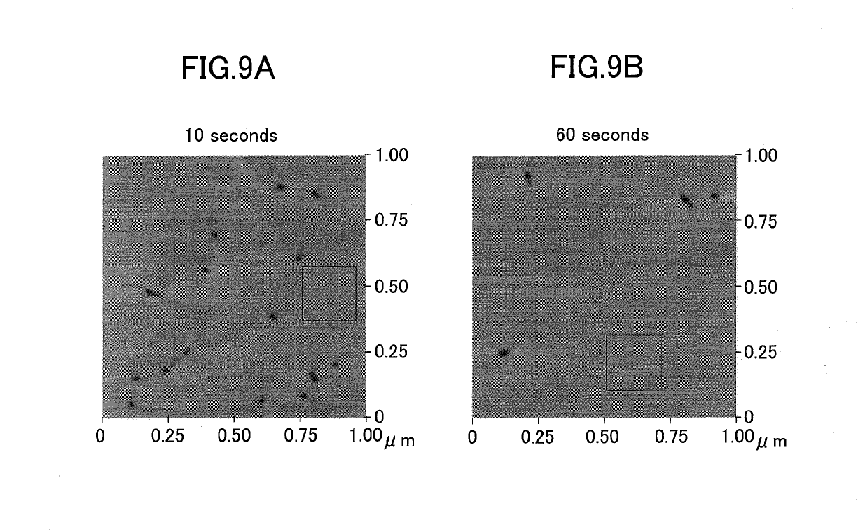

FIGS. 9A and 9B illustrate the AFM images of the surface of the electron transit layer 22. Specifically, FIG. 9A illustrates the AFM image of the electron transit layer 22 when the buffer layer 21 and the electron transit layer 22 are formed on the nitride layer 11 where the forming time period is ten seconds (i.e., the case of FIG. 8A).

FIG. 9B illustrates the AFM image of the electron transit layer 22 when the buffer layer 21 and the electron transit layer 22 are formed on the nitride layer 11 where the forming time period is sixty seconds (i.e., the case of FIG. 8C). The number of defects found on the surface in FIG. 9B is less than that on the surface in FOG. 9A.

Therefore, by increasing the forming time period, it may become possible to reduce the number of defects on the electron transit layer 22, thereby improving the crystal quality. Also, by doing this, the on-resistance value of the HEMT which is the formed semiconductor apparatus may be decreased.

### Third Embodiment

Next, a third embodiment is described. In this embodiment, a semiconductor device, a power-supply apparatus, and a high-frequency amplifier are provided.

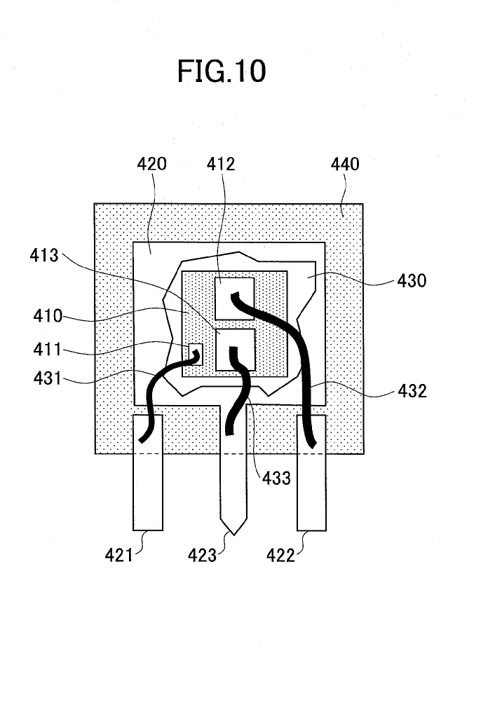

The semiconductor device in this embodiment herein refers to a discretely-packaged semiconductor apparatus according to the second embodiment. FIG. 10 schematically illustrates the inside of the discretely-packaged semiconductor apparatus. However, the arrangement of the electrodes differs from that illustrated in the figure in the second embodiment.

First, an HEMT semiconductor chip 410 using GaN-based semiconductor material is formed by cutting the semiconductor apparatus, which is manufactured according to the second embodiment, by dicing or the like. Then the semiconductor chip 410 is fixed on a lead frame 420 with a die bonding agent such as solder. Here, the semiconductor chip 410 corresponds to the semiconductor apparatus in the second embodiment.

Next, a gate electrode 411 is connected to a gate lead 421 with a bonding wire 431, a source electrode 412 is connected to a source lead 422 with a bonding wire 432, and a drain electrode 413 is connected to a drain lead 423 with a bonding wire 433.

Here, the bonding wires 431, 432, and 433 are formed of a metal material. Further, in this embodiment, the gate electrode 411 refers to the gate electrode pad which is connected to the gate electrode 51 in the semiconductor apparatus according to the second embodiment. Similarly, the source electrode 412 refers to the source electrode pad which is connected to the source electrode 52 in the semiconductor apparatus according to the second embodiment. The drain electrode 413 refers to the drain electrode pad which is connected to the drain electrode 53 in the semiconductor apparatus according to the second embodiment.

Next, resin-sealing is performed with a mold resin 440 by the transfer mold method. By doing this, it becomes possible to manufacture the discretely-packaged semiconductor device of the HEMT using GaN-based semiconductor material.

Next, a power-supply apparatus and a high-frequency amplifier according to this embodiment are described. The power-supply apparatus and the high-frequency amplifier according to this embodiment refer to the power-supply apparatus and the high-frequency amplifier using the semiconductor apparatus according to the second embodiment.

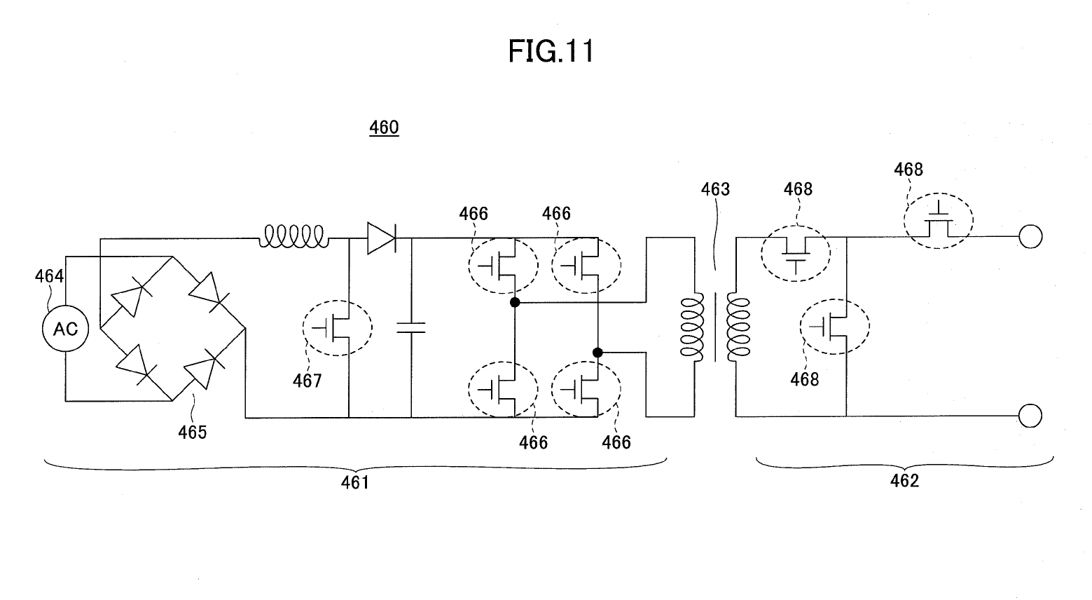

First, with reference to FIG. 11, the power-supply apparatus according to this embodiment is described. The power-supply apparatus 460 includes a high-voltage primary circuit 461, a low-voltage secondary circuit 462, and a transformer 463 which is disposed between the primary circuit 461 and the secondary circuit 462.

The primary circuit 461 includes an alternating-current (AC) source 464, a so-called bridge rectifier circuit 465, a plurality of switching devices (four switching devices in the example of FIG. 11) 466, a single switching device 467 and the like.

The secondary circuit 462 includes a plurality of switching devices (three switching devices in the example of FIG. 11) 468 and the like. In the example of FIG. 11, the semiconductor apparatus according to the first embodiment is used as the switching devices 466 and 467.

Here, it is desired that the switching devices 466 and 467 in the primary circuit 461 be normally-off semiconductors. As the switching devices 468 used in the secondary circuit 462, typical metal insulator semiconductor field effect transistors (MISFET) formed of silicon are used.

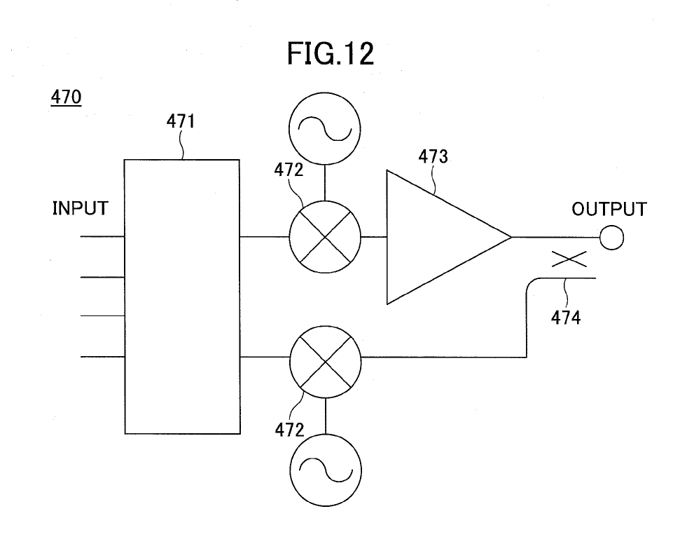

Next, with reference to FIG. 12, the high-frequency amplifier according to this embodiment is described. The high-frequency amplifier 470 according to this embodiment may be used as, for example, a high-power amplifier for a base station of cellular phones.

The high-frequency amplifier 470 includes a digital predistortion circuit 471, a mixer 472, a power amplifier 473, and a directional coupler 474. The digital predistortion circuit 471 compensates non-linear distortion of the input signals.

The mixer 472 mixes the input signals, whose non-linear distortion has been compensated, with an AC signal. The power amplifier 473 amplifies the input signal that has been mixed with the AC signal. In the example of FIG. 12, the power amplifier 473 includes the semiconductor apparatus according to the first embodiment.

The directional coupler 474 performs monitoring on the input signal and the output signal and the like. In the circuit of FIG. 12, by a switching operation, the output signal may be mixed with the AC signal by the mixer 472 and transmitted to the digital predistortion circuit 471.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of superiority or inferiority of the invention. Although the embodiment of the present inventions has been described in detail, it is to be understood that various changes, substitutions, and alterations could be made hereto without departing from the spirit and scope of the invention.

What is claimed is:

1. A method of manufacturing a semiconductor crystal substrate, the method comprising:
forming a nitride layer by supplying a gas including a nitrogen component to a substrate formed of a material including silicon and thereby nitriding a surface of the substrate; and
forming an AlN layer on the nitride layer by supplying the gas including the nitrogen component and a source gas including Al.

2. The method according to claim 1,
wherein the gas including the nitrogen component is ammonia.

3. The method according to claim 1,
wherein a temperature of the substrate when the nitride layer is formed is in a range from 800 degrees Celsius to 1,100 degree Celsius.

4. The method according to claim 1,
wherein a thickness of the nitride layer is in a range from 2 nm to 5 nm.

5. The method according to claim 1,
wherein the nitride layer is formed of a material including silicon nitride (SiN).

6. The method according to claim 1,
wherein the AlN layer is formed by MOCVD.

7. A method of manufacturing a semiconductor apparatus, the method comprising:
forming a buffer layer on the AlN layer of the semiconductor crystal substrate manufactured based on the method according to claim 1;
forming an electron transit layer on the buffer layer; and
forming an electron supply layer on the electron transit layer.

8. The method according to claim 7, further comprising:
forming a gate electrode, a source electrode, and a drain electrode on the electron supply layer.

9. The method according to claim 7,
wherein the buffer layer, the electron transit layer, and the electron supply layer are formed by MOCVD,
wherein the buffer layer is formed of a material including AlGaN,
wherein the electron transit layer is formed of a material including GaN, and
wherein the electron supply layer is formed of a material including AlGaN.

10. A semiconductor crystal substrate comprising:
a substrate formed of a material including silicon;
a nitride layer formed on the substrate and formed of a material including silicon and nitrogen; and
an AlN layer formed on the nitrogen layer.

11. The semiconductor crystal substrate according to claim 10,
wherein a thickness of the nitride layer is in a range from 2 nm to 5 nm.

12. The semiconductor crystal substrate according to claim 10,
wherein the nitride layer is formed of a material including silicon nitride (SiN).

13. The semiconductor crystal substrate according to claim 10,
wherein the substrate is a silicon substrate.

14. A semiconductor apparatus comprising:
a substrate formed of a material including silicon;
a nitride layer formed on the substrate and formed of a material including silicon and nitrogen;
an AlN layer formed on the nitride layer;
an electron transit layer formed on the AlN layer; and
an electron supply layer formed on the electron transit layer.

15. The semiconductor apparatus according to claim 14,
wherein the substrate is a silicon substrate.

16. The semiconductor apparatus according to claim 14, further comprising:
a buffer layer formed between the AlN layer and the electron transit layer,
wherein the buffer layer is formed of a material including AlGaN.

17. The semiconductor apparatus according to claim 14,
wherein the electron transit layer is formed of a material including GaN, and
wherein the electron supply layer is formed of a material including AlGaN.

18. The semiconductor apparatus according to claim 14,
wherein a gate electrode, a source electrode, and a drain electrode are formed on the electron supply layer.

19. A power-supply apparatus comprising:
the semiconductor apparatus according to claim 14.

20. An amplifier comprising:
the semiconductor apparatus according to claim 14.
